(19) United States
(12) Patent Application Publication
(10) Pub. No.: US 2005/0178611 A1
(43) Pub. Date: Aug. 18, 2005

(54) Low frequency loudspecker enclosure with configurable directivity

(76) Inventors: Guido Noselli, Flero (IT); Stefano Noselli, Flero (IT); Michele Noselli, Flero (IT)

Correspondence Address: MCGLEW & TUTTLE, PC, P.O. BOX 9227, SCARBOROUGH STATION, SCARBOROUGH, NY, 10510-9227, US

(21) Appl. No.: 10/517,300

(22) PCT Filed: Feb. 10, 2003
(86) PCT No.: PCT/IT03/00065

(30) Foreign Application Priority Data
Jun. 24, 2002 (IT) BS2002A000060

(51) Int. Cl. H05K 5/00; A47B 81/06

(52) U.S. Cl. 181/145; 181/199

(57) ABSTRACT

This invention relates to a low frequency loudspeaker (sub woofer), which comprises at least one pair of loudspeakers mounted in the same box, facing in opposite directions and powered as separate elements by signals coming form a single source but having different amplitude and phase.

### FILED OF INVENTION

This invention regards loudspeaker enclosures, in particular for low frequencies.

### STATE OF THE ART

More than in the past, today's requirements for the reproduction of music and speech, for live applications and professional or other purposes require the use of enclosures suited to achieving the objective.

These enclosures have increasing need for control of their emission directivity, to ensure high quality high-level reproduction only in the required areas.

It's a well-known fact that directivity control is linked with the dimensions of the sound system, or prior to that, with those of the specific elements it's made up of. These dimensions are in turn linked with the wavelengths of the frequencies or frequency bands that the aforementioned elements must reproduce. For example, controlling a frequency band from 1000 Hz to 20000 Hz in order to measure the attenuation of 6 dB at the required dispersion, the parameter conventionally chosen to identify the dispersion of an enclosure or sound reinforcement system, means that the component, loudspeaker or system which must control the angular emission of this band must have a dimension of at least 2λ of the minimum frequency to be controlled on the plane(s) on which this control has to be carried out: in this example, no less than 68 cm. (344/1000*2)

Without going into the details of a description of the various solutions sought to achieve this objective, on which abundant technical/commercial documentation already exists, as the dimensions necessary for mid and high frequencies are still limited, the aim of achieving high directivity has been amply achieved using various types of horn enclosures or more recently in vertical line array configurations, with their parameters controlled by DSP (Digital Signal Processors), able to make these modular enclosure configurations assume different angular dispersion patterns.

For the mid low, low or sub low frequencies on the other hand, obtaining high directivity is a problem which isn't easily solved, due to the larger dimension the enclosures must in some way assume when one wants to control these frequencies, dimensions that become increasingly larger the lower the bands of frequencies to be reproduced with narrow angular dispersion become.

For example, if its necessary to control a frequency band starting from 100 Hz in an enclosure or system of enclosures (in this case not only vertical line arrays, but also and more simply, groups of enclosures closely coupled together), the dimensions required are very large. In fact, 2λ of 100 Hz is 6.8 m, a dimension that for an enclosure, or even a group of enclosures, is obviously rather unmanageable from all points of view. If one then considers that although classified as low frequencies, frequencies such as 100 Hz are not the only ones which must be reproduced at high sound level in the professional field, and 50/40 or 30 Hz must also be reproduced with the same energy in order to ensure complete sound reproduction, it's obvious that the dimensions sound systems or enclosures would need to have to control their directivity become even larger; for example, 2λ of 30 Hz is approximately 23 m!

This “normally” also happens in the case of horn enclosures or systems, sometimes preferred where large dimensions are not a hindrance to their use, for greater transduction efficiency, not only for direct radiation models because, in both cases, the directivity (or rather the gradual lack of directivity as frequencies become lower and lower) is established by the well known phenomenon of diffraction.

It's therefore obvious that to control dispersion at low frequencies it's necessary to take another direction or integrate the technique already known, essentially regarding the dimensions of a horn or the dimensions of the baffle in a direct radiating system (or even indirect radiating, such as a passband system), with other “expedients” aimed at increasing directivity.

Well known examples of these “expedients” can be found in numerous acoustic engineering books by authors who made audio history, such as Olson and Beranek, to mention just the most famous. These “expedients” are based on interference methods, which were and still are applied nowadays to microphones, for which it has always been necessary to control their directivity in relation to the signal they pick up for various reasons, such as immunity from background noise from directions other than that of the sound they're used to pick up, capacity to pick up weak far-off sounds, insensibility to feedback, etc.

Through the years, some projects of low frequency enclosures using these “expedients” have been proposed, without however meeting with particular success, perhaps due to a question of all-round performance and/or performance:price ratio.

Recently however there has been a revival of these techniques, due to requests for limiting dispersion at low frequencies becoming more and more insistent, but also the possibility of applying to the aforementioned systems the necessary sophisticated “regulations” suitable for controlling directivity by means of “interference”, which modern electronics and use of DSP units for audio processing enable to be easily done at relatively low costs.

In fact, having the possibility of applying different delays or phase shifts to the sound sources used together to obtain a given directivity is no longer a costly almost unattainable procedure as it was generally speaking even just about ten years ago.

Systems have therefore appeared on the market for the reproduction of low frequencies that apply techniques such as those described and are able to reproduce audio signals starting from 30/40 Hz with dispersion patterns similar to those obtained in various types of microphones, such as cardioid, super-cardioid or hyper-cardioid to mention the best known.

These enclosures were built, with the appropriate variations, solutions adopted for microphones were used, regarding which there's a great deal of detailed literature, as microphones are the inverse of loudspeakers. Regarding this, for information purposes and as a significant example, it's worth mentioning a study by Marinus M. Boone and Okke Ouweltjes published in the JAES Vol. 45 N° 9, Sep. 1997, entitled “Design of a Loudspeaker System with a Low-Frequency Cardiodlike Radiation Pattern”.

### AIMS AND SUMMARY OF INVENTION

One aim of this invention is to propose and supply a new, original set-up for a dedicated loudspeaker enclosure, able to give polar dispersion at low frequencies, no longer with a distribution of practically 360°, but according to needs, changed into one or more of the various listed dispersion patterns.

Yet another of the invention's aims is to supply a sound system for low frequencies that has a simplified construction design, enabling it to be used as a traditional system, but when necessary, controlled electronically to vary its electro-acoustic configuration and obtain the controlled dispersion described above.

Then another aim of the invention is to build an improved speaker enclosure for low frequencies with configurable directivity, at the same time maintaining very compact overall dimensions, great construction simplicity and user-friendly regulation which keep costs low and price:performance:directivity ratio high.

These aims have been achieved, in accordance with the invention, with a speaker enclosure for low frequencies at least according to claim 1.

### BRIEF DESCRIPTION OF DRAWINGS

The innovation proposed here will be described in greater detail in the continuation and referring to the attached designs, which are given as an indication, are not restrictive and in which:

FIG. 1 shows a front view of the low frequency speaker enclosure (subwoofer) with variable directivity;

FIG. 1A shows the cross-section of the enclosure according to the A-A arrows in FIG. 1;

FIG. 1B shows another cross-section of the enclosure according to the B-B arrows in FIG. 1;

FIG. 2 shows a constructional variation of the enclosure according to the invention;

FIG. 3 shows an acoustic and electric operating diagram of the system according to the analogy of the equivalent electric circuits;

FIGS. 4, 5 and 6 show the same number of horizontal/vertical polar curves of the low frequency loudspeaker system in compliance with the invention.

### DETAILED DESCRIPTION OF THE INVENTION

The low frequency enclosure or subwoofer shown is equipped with two loudspeakers (Spk1 & Spk2) fitted in a single box (V1) with very compact dimensions, for example 70×60×50 cm. The two loudspeakers can also, with no limitations, be different from one another (e.g. one 18″ and the other 15″) and point in opposite directions, one towards the front, the other towards the back. Inside the box (V1), on at least two sides of the front loudspeaker two conduits (P1, P2) are foreseen, while the rear loudspeaker faces into a chamber (V2) with side openings (P3, P4, P5). Basically, the two loudspeakers have the same volume of air and the same generator (FIG. 3) in common, but are powered as separate elements with signals which have a different amplitude and phase by two separate amplification circuits (11, 12) which include, among other things, an electronic delay circuit 13, 14.

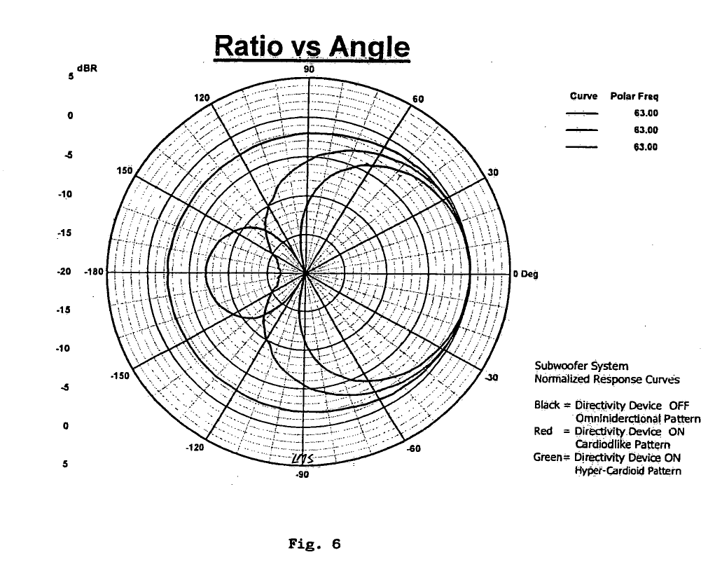

If necessary when omnidirectional low frequency dispersion isn't required, this geometric layout (when electronically assisted) FIG. 4 allows a great attenuation of rear emission, by exploiting the interference phenomenon from 30/40 Hz up to frequencies of over 100/120 Hz, giving dispersion patterns like those shown in FIGS. 5 and 6.

In particular, FIG. 4 shows the horizontal/vertical polar curves of the subwoofer system measured in half space (2π) with the microphone at four meters without activating the system for the attenuation of rear emission at low frequencies according to this invention.

It should be noted that the system is basically omnidirectional over the entire operating band. Amplitude (parallel lines)=1 dB. Degrees (Meridians)=10°.

FIG. 5 shows the system subwoofer horizontal/vertical polar curve measured in half space (2π) with the microphone at four meters and activating the system for the attenuation of rear emission at low frequencies according to this invention.

It should be noted that the system has cardioid-type rear radiation over the entire operating band. Amplitude (parallel lines)=1 dB Degrees (Meridians)=10°.

FIG. 6 shows the horizontal/vertical polar curves of the subwoofer system. For the 63 Hz ⅓ octave band, the polar responses measured in half space (2π) with a microphone at four meters are compared directly:
Omnidirectional, without activating the system for rear attenuation of low frequencies,
Cardioid-like, activating the system set for this dispersion pattern,
Hypercardioid-like, activating the system set for this dispersion pattern.

Note must be taken of the great difference in energy that the system gives at the rear at low frequencies according to the various dispersion patterns obtained with the dedicated settings (for convenience, 63 Hz was taken as centre ⅓ octave of the reproduced band). Amplitude (parallel lines)=1 dB. Degrees (Meridians)=10°.

Its compact dimensions and low weight also make it an element that can be easily stacked or flown in multiples to form vertical line arrays, but can also more traditionally be installed close together in multiples to form horizontal line arrays or in any case groups of acoustically coupled elements and operating in “piston band” conditions.

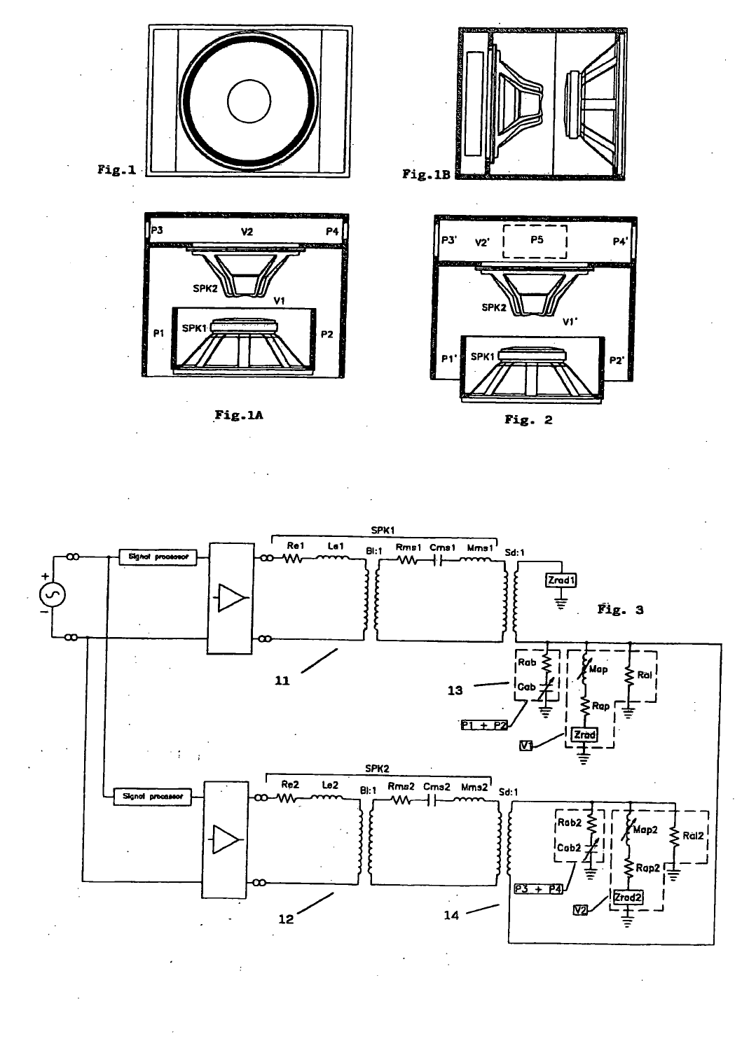

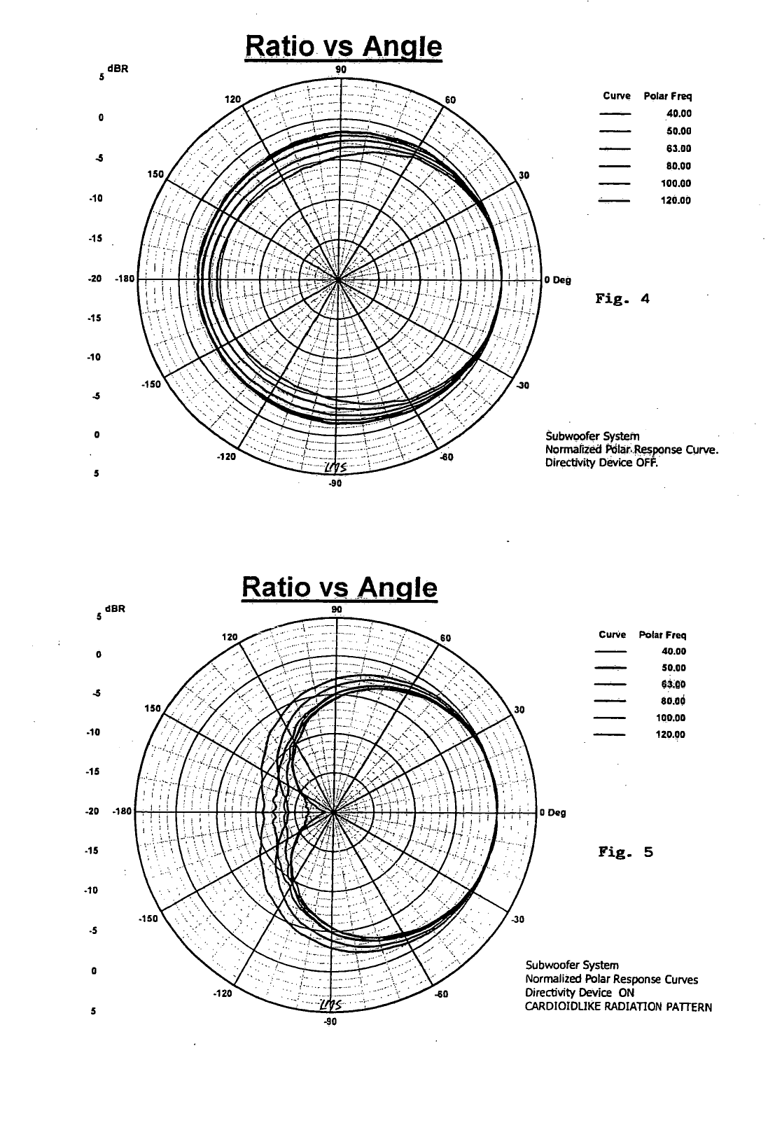

Another important aspect of this in the invention consists in the possibility of varying the construction geometry without altering its simplicity, in order to be able to modify the entity of the acoustic parameters involved, established by volumes and dimensions of the conduits or apertures, in order to obtain acoustic performance which differs from the point of view of amplitude and passband reproduced. This other aspect is shown in FIG. 2, in which the same alphanumerical data with the addition of (′) to show parts which are identical or equivalent to those shown in FIG. 1 have been used.

1. A low frequency loudspeaker enclosure (subwoofer), characterized by the fact that it includes at least one pair of loudspeakers mounted in the same box, facing the opposite directions and powered as separate elements by signals coming from a single source but having different amplitude and phase.

2. The low frequency loudspeaker enclosure according to claim 1, in which a first loudspeaker faces towards the front and a second loudspeaker towards the rear, in order to send the sound in the opposite directions, said loudspeakers being identical or different from one another and driven by amplification circuits, each including an electronic delay circuit.

3. The low frequency loudspeaker enclosure according to claim 1, in which two open conduits are provided on at least two sides of the front loudspeaker, and in which the rear loudspeaker faces on to a chamber having two side openings.

4. The low frequency loudspeaker enclosure according to claim 3, in which said front loudspeaker is contained in the box or protrudes from the front of it.

5. The low frequency loudspeaker enclosure according to claim 3, in which said conduits and/or side apertures have variable dimensions to modify the system's acoustic parameters.

6. The low frequency loudspeaker enclosure according to claim 1, which can be placed alongside or stacked on other enclosures to form horizontal and vertical arrays, or coupled and installed one above the other in multiples to form groups operating in a “piston band” set-up.

7. Method of constructing a low frequency loudspeaker enclosures which comprises:
the use of at least a pair of loudspeakers, mounted in the same box, facing in opposite directions compared to the sound emission, one facing forward and the other backwards on to a chamber having side openings;
the powering of the aforementioned loudspeakers as separate elements with signals, coming from a single source but with different amplitude and phase, by using separate amplification circuits, each including an electronic delay circuit, and
the possibility of varying the reciprocal entity of the enclosure's acoustic parameters, modifying the load volume of the loudspeaker and/or dimensions of the conduits/apertures on the front and/or apertures positioned at the rear, in order to obtain different dispersion patterns.

8. The low frequency loudspeaker enclosure according to claim 2, in which two open conduits are provided on at least two sides of the front loudspeaker, and in which the rear loudspeaker faces on to a chamber having two side openings.

9. The low frequency loudspeaker enclosure according to claim 4, in which said conduits and/or side apertures have variable dimensions to modify the system's acoustic parameters.

10. The low frequency loudspeaker enclosure according to claim 2, which can be placed alongside or stacked on other enclosures to form horizontal and vertical arrays, or coupled and installed one above the other in multiples to form groups operating in a “piston band” set-up.

11. The low frequency loudspeaker enclosure according to claim 3, which can be placed alongside or stacked on other enclosures to form horizontal and vertical arrays, or coupled and installed one above the other in multiples to form groups operating in a “piston band” set-up.

12. The low frequency loudspeaker enclosure according to claim 4, which can be placed alongside or stacked on other enclosures to form horizontal and vertical arrays, or coupled and installed one above the other in multiples to form groups operating in a “piston band” set-up.

13. The low frequency loudspeaker enclosure according to claim 5, which can be placed alongside or stacked on other enclosures to form horizontal and vertical arrays, or coupled and installed one above the other in multiples to form groups operating in a “piston band” set-up.
